(19) United States
(12) Patent Application Publication
(10) Pub. No.: US 2025/0096208 A1
(43) Pub. Date: Mar. 20, 2025

(54) SEMICONDUCTOR PACKAGE HAVING DIELECTRIC LAYER WITH STEP DIFFERENCE

(71) Applicant: SAMSUNG ELECTRONICS CO., LTD., Suwon-si (KR)

(72) Inventors: Jeongoh HA, Suwon-si (KR); Juhyeon Kim, Suwon-si (KR); Chajea Jo, Suwon-si (KR)

(73) Assignee: SAMSUNG ELECTRONICS CO., LTD., Suwon-si (KR)

(21) Appl. No.: 18/674,004

(22) Filed: May 24, 2024

(30) Foreign Application Priority Data
Sep. 20, 2023 (KR) 10-2023-0125608

(51) Int. Cl. H01L 25/10; H01L 23/00; H01L 23/31; H01L 23/48; H01L 23/498

(52) U.S. Cl. CPC H01L 25/105; H01L 23/3107; H01L 23/481; H01L 23/49816; H01L 24/08; H01L 24/80; H01L 24/96; H01L 2224/08145; H01L 2224/80895; H01L 2224/80896; H01L 2224/96; H01L 2225/1082

(57) ABSTRACT

A semiconductor package includes a first semiconductor chip having first and second surfaces opposing each other; first lower electrode pads on the first surface; a first insulating layer surrounding a side surface of each of the first lower electrode pads on the first surface; through-electrodes penetrating through at least a portion of the first semiconductor chip; first upper electrode pads on the through-electrodes; a first dielectric layer covering at least a portion of each of the first insulating layer, the first semiconductor chip, the through-electrodes, and the first upper electrode pads on the through-electrodes; where the first dielectric layer comprises a first portion and a second portion on the first portion of the first dielectric layer, and a first outer surface of the first portion is located on an inner side closer to the first semiconductor chip than a second outer surface of the second portion.

### CROSS-REFERENCE TO RELATED APPLICATION(S)

This application claims benefit of priority to Korean Patent Application No. 10-2023-0125608 filed on Sep. 20, 2023 in the Korean Intellectual Property Office, the disclosure of which is incorporated herein by reference in its entirety.

### BACKGROUND

### 1. Field

The embodiments of the present disclosure relate to a semiconductor package, and more specifically, to the formation of a semiconductor package using an alignment key resulting in a dielectric layer with a step difference.

### 2. Related Art

Semiconductor packaging technology has been actively researched in accordance with the trend for higher performance and miniaturization of electronic devices. In three-dimensional integrated circuit (3D-IC) technology, which integrates heterogeneous semiconductor chips, efforts have been made to develop technology for stacking electrically connected semiconductor chips vertically. However, the processes are complex, and may not result in accurate stacking of semiconductor chips.

### SUMMARY

An aspect of the present embodiments is to provide a semiconductor package having simplified processes and improved reliability.

According to one or more embodiments, a semiconductor package comprises: a first semiconductor chip having first and second surfaces opposing each other; first lower electrode pads on the first surface of the first semiconductor chip and electrically connected to the first semiconductor chip; a first insulating layer surrounding a side surface of each of the first lower electrode pads on the first surface of the first semiconductor chip; through-electrodes penetrating through at least a portion of the first semiconductor chip and protruding from the second surface of the first semiconductor chip; first upper electrode pads on the through-electrodes and electrically connected to the first semiconductor chip through the through-electrodes; a first dielectric layer covering at least a portion of each of the first insulating layer, the first semiconductor chip, the through-electrodes, and the first upper electrode pads on the through-electrodes; a second semiconductor chip on the first dielectric layer; second electrode pads on a first surface of the second semiconductor chip and electrically connected to the second semiconductor chip and the first upper electrode pads on the through-electrodes; a second insulating layer surrounding side surfaces of the second electrode pads on the first surface of the second semiconductor chip; a second dielectric layer covering at least a portion of each of the second semiconductor chip and the second insulating layer; bump structures patched below the first lower electrode pads on the first surface of the first semiconductor chip; and a protective layer covering at least a portion of the bump structures, wherein the first dielectric layer comprises a first portion and a second portion on the first portion of the first dielectric layer, and a first outer surface of the first portion of the first dielectric layer is located on an inner side that is closer to the first semiconductor chip than a second outer surface of the second portion of the first dielectric layer.

According to one or more embodiments, a semiconductor package comprises: first and second chip structures stacked in a first direction, wherein the first chip structure incudes: a first semiconductor chip, first lower electrode pads electrically connected to the first semiconductor chip, a first insulating layer surrounding each of the first lower electrode pads, through-electrodes penetrating through at least a portion of the first semiconductor chip, first upper electrode pads on the through-electrodes, and a first dielectric layer covering a portion of each of the first insulating layer, the first semiconductor chip, the through-electrodes, and the first upper electrode pads on the through-electrodes, wherein the second chip structure comprises: a second semiconductor chip, second electrode pads electrically connected to the second semiconductor chip and the first upper electrode pads on the through-electrodes, a second insulating layer surrounding the second electrode pads and contacting the first dielectric layer, and a second dielectric layer covering at least a portion of each of the second semiconductor chip and the second insulating layer, wherein the first dielectric layer comprises a first portion surrounding at least a portion of a side surface of the first insulating layer and a second portion surrounding a side surface of the first semiconductor chip, and a first outer surface of the first portion and a second outer surface of the second portion have a step difference.

According to one or more embodiments, a semiconductor package comprises a first semiconductor chip; first lower electrode pads below the first semiconductor chip and electrically connected to the first semiconductor chip; a first insulating layer surrounding a side surface of each of the first lower electrode pads; through-electrodes penetrating through at least a portion of the first semiconductor chip and protruding from an upper surface of the first semiconductor chip; first upper electrode pads on the through-electrodes and electrically connected to the first semiconductor chip through the through-electrodes; a first dielectric layer covering a portion of each of the first insulating layer, the first semiconductor chip, the through-electrodes, and the first upper electrode pads on the through-electrodes; a second semiconductor chip on the first dielectric layer; second electrode pads on a first surface of the second semiconductor chip and electrically connected to the second semiconductor chip and the first upper electrode pads on the through-electrodes; and a second insulating layer surrounding side surfaces of the second electrode pads on the first surface of the second semiconductor chip, wherein the first dielectric layer comprises a first portion having a first width and a second portion having a second width greater than the first width on the first portion.

### BRIEF DESCRIPTION OF DRAWINGS

The above and other aspects, features, and advantages of the present embodiments will be more clearly understood from the following detailed description, taken in conjunction with the accompanying drawings, in which:

FIG. 1 is a cross-sectional view illustrating a semiconductor package according to example embodiments;

FIGS. 2A to 2F are enlarged views of region A of FIG. 1 according to example embodiments;

FIGS. 3A to 3B are plan views taken along line I-I′ of FIG. 1 according to example embodiments;

FIG. 4 is a cross-sectional view illustrating a semiconductor package according to example embodiments;

FIGS. 5 to 7 are cross-sectional views illustrating semiconductor package structures according to example embodiments; and

FIGS. 8 to 35 are views illustrating a manufacturing process of a semiconductor package according to example embodiments.

### DETAILED DESCRIPTION

Hereinafter, example embodiments will be described with reference to the accompanying drawings. Hereinafter, terms, such as ‘top,’ ‘upper portion,’ ‘upper surface,’ ‘bottom,’ ‘lower portion,’ ‘lower surface,’ and ‘side surface’ may be understood as referring to based on drawings, except for cases indicated by reference numerals.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

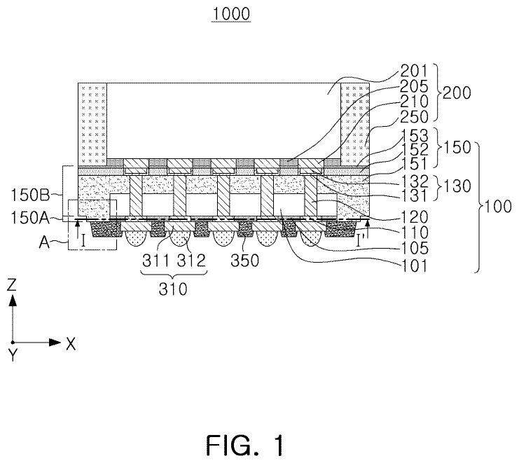

FIG. 1 is a cross-sectional view illustrating a semiconductor package according to example embodiments.

Referring to FIG. 1, a semiconductor package 1000, according to example embodiments, may include a first chip structure 100, a second chip structure 200, bump structures 310, and a protective layer 350. The first chip structure 100 may include a first semiconductor chip 101, a first insulating layer 105, first lower electrode pads 110, through-electrodes 120, first upper electrode pads 130, and a first dielectric layer 150. The second chip structure 200 may include a second semiconductor chip 201, a second insulating layer 205, second electrode pads 210, and a second dielectric layer 250.

Hereinafter, unless otherwise defined, in one or more examples, ‘height’ refers to a thickness or distance in a Z-direction on the drawing, and ‘width’ refers to a distance in an X-direction on the drawing or a thickness or a distance in a Y-direction on the drawing.

The first semiconductor chip 101 and the second semiconductor chip 201 may include logic chips including a central processing unit (CPU), a graphics processing unit (GPU), a field programmable gate array (FPGA), a digital signal processor (DSP), an encryption processor, a microprocessor, a microcontroller, an analog-to-digital converter, etc., The first semiconductor chip 101 and the second semiconductor chip 201 may further include memory chips including a volatile memory (e.g., DRAM, SRAM, etc.), and/or a non-volatile memory (e.g., PRAM, MRAM, FeRAM, RRAM, flash memory, etc.).

The number of second semiconductor chips 201 stacked vertically or

horizontally on the first semiconductor chip 101 may be two or more. For example, the first semiconductor chip 101 may include a logic chip, such as an application specific integrated circuit (ASIC), and the second semiconductor chip 201 may include a memory chip providing cache information to the first semiconductor chip 101. The size of the second semiconductor chip 201 may be smaller than the size of the first semiconductor chip 101. For example, a planar area of the second semiconductor chip 201 may be less than a planar area of the first semiconductor chip 101. According to example embodiments, a height of the second semiconductor chip 201 may be higher than a height of the first semiconductor chip 101.

The first semiconductor chip 101 may have upper and lower surfaces opposing each other. These surfaces may also interchangeably be referred to as first and second surfaces. The first semiconductor chip 101 may include a semiconductor wafer including a semiconductor element, such as silicon or germanium and a compound semiconductor, such as silicon carbide (SiC), gallium arsenide (GaAs), indium arsenide (InAs), and indium phosphide (InP). A lower surface of the semiconductor wafer may be an active surface having an active region doped with impurities, and an upper surface of the semiconductor wafer may be an inactive surface without an active region. The first semiconductor chip 101 may include a first circuit layer on the active surface. The first circuit layer may include an integrated circuit including individual devices and an interconnection structure electrically connecting the individual devices to the first lower electrode pads 110. The ‘individual devices’ may include memory devices, such as field effect transistor (FET) devices, such as planar FET or FinFET, flash memory, DRAM, SRAM, EEPROM, PRAM, MRAM, FeRAM, RRAM, logic devices, such as AND, OR, NOT, etc., The ‘individual devices’ may further include various active and/or passive devices, such as system LSI, CIS, and MEMS.

The first insulating layer 105 may be disposed on a lower surface of the first semiconductor chip 101 to surround side surfaces of each of the first lower electrode pads 110. For example, the first insulating layer 105 may include at least one of silicon oxide (SiO), silicon nitride (SiN), and silicon carbonitride (SiCN).

The first lower electrode pads 110 may be disposed on the lower surface of the first semiconductor chip 101 and may be electrically connected to the first semiconductor chip 101. In example embodiments, the first lower electrode pads 110 may be connection terminals electrically connected to an integrated circuit within the first semiconductor chip 101. The first lower electrode pads 110 may include any one of copper (Cu), nickel (Ni), titanium (Ti), aluminum (Al), gold (Au), silver (Ag), or alloys thereof. In example embodiments, the first lower electrode pads 110 may be connection terminals (e.g., aluminum pads) of a bare chip. In example embodiments, the first lower electrode pads 110 may be a connection structure (e.g., a copper pad) disposed on the connection terminal of the bare chip. As understood by one of ordinary skill in the art, a bare chip may be an integrated circuit that has been cut out of a wafer and is ready for packaging. A barrier layer including at least one of titanium (Ti), titanium nitride (TiN), tantalum (Ta), and tantalum nitride (TaN) may be disposed between the first lower electrode pads 110 and the first insulating layer 105.

The through-electrodes 120 may electrically connect the first lower electrode pads 110 to the first upper electrode pads 130. The through-electrodes 120 may be electrically connected to the first lower electrode pads 110 and protrude from an upper surface of the first semiconductor chip 101. The through-electrodes 120 may include a via plug and a side barrier film surrounding the side of the via plug. The ‘via plug’ may include, for example, tungsten (W), titanium (Ti), aluminum (Al), or copper (Cu), and may be formed through a plating process, PVD process, or CVD process. The ‘side barrier film’ may include titanium (Ti), titanium nitride (TiN), tantalum (Ta), or tantalum nitride (TaN), and may be formed through a plating process, PVD process, or CVD process. A side insulating film including an insulating material, such as silicon oxide, silicon nitride, or silicon oxynitride may be disposed between the through-electrodes 120 and the first semiconductor chip 101.

Each of first upper electrode pads 130 may be disposed on a respective through-electrode 120. The first upper electrode pads 130 may be spaced apart from the first semiconductor chip 101, and a first dielectric layer 150 may be formed between the first upper electrode pads 130 and the upper surface of the first semiconductor chip 101. The first upper electrode pads 130 may each include a conductive layer 132 and a seed layer 131 covering the side and lower surfaces of the conductive layer 132. The conductive layer 132 may include any one of copper (Cu), nickel (Ni), aluminum (Al), gold (Au), and silver (Ag) or alloys thereof, and the seed layer 131 may include titanium (Ti) or an alloy of titanium (Ti).

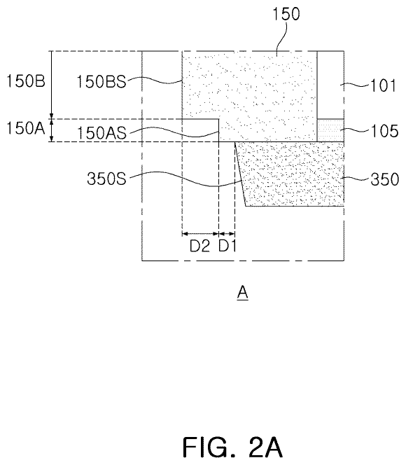

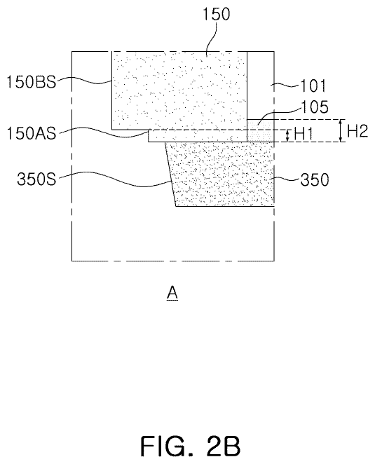

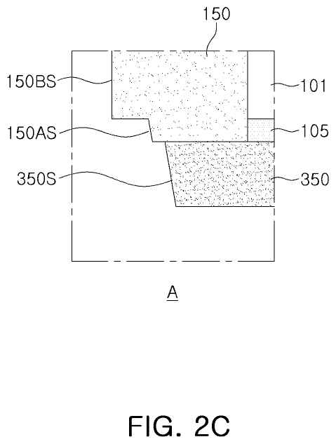

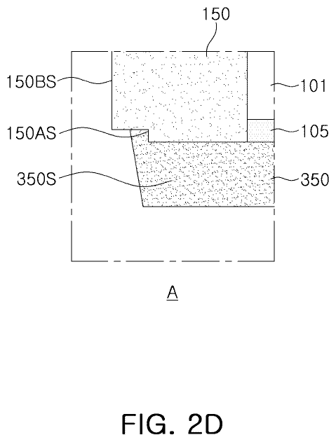

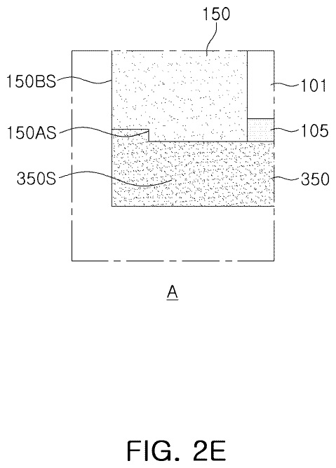

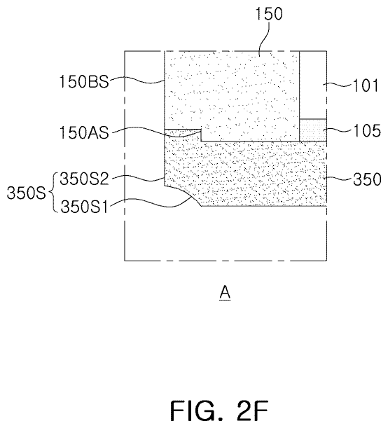

The first dielectric layer 150 may cover at least a portion of the first insulating layer 105, the first semiconductor chip 101, the through-electrodes 120, and the first upper electrode pads 130. The first dielectric layer 150 may include a first portion 150A and a second portion 150B on the first portion 150A. The first portion 150A may surround at least a portion of the side surface of the first insulating layer 105, and the second portion 150B may surround at least a portion of the side surface of the first semiconductor chip 101. The first dielectric layer has a step structure such that an outer surface 150AS (see FIG. 2A) of the first portion 150A may be located on an inner side that is closer to the first semiconductor chip 101 than an outer surface 150BS (see FIG. 2A) of the second portion 150B. These features are described in detail in the description of FIGS. 2A to 2F, and redundant descriptions are omitted in the description of FIG. 1.

The first dielectric layer 150 may include a first lower dielectric layer 151 and first upper dielectric layers 152 and 153. The first lower dielectric layer 151 may surround the side surface of the first insulating layer 105 and the side surface of each of the through-electrodes 120. An upper surface of the first lower dielectric layer 151 may be located on substantially the same level as that of the upper surface of the through-electrodes 120. The first lower dielectric layer 151 may include the entirety of the first portion 150A and at least a portion of the second portion 150B. The first upper dielectric layers 152 and 153 may surround the side surfaces of each of the first upper electrode pads 130 on the first lower dielectric layer 151 and may be in contact with the second insulating layer 205. The first upper dielectric layers 152 and 153 may include a plurality of dielectric layers.

In one or more examples, the first dielectric layer 150 may include at least one of silicon oxide (SiO), silicon nitride (SiN), and silicon carbonitride (SiCN). The first lower dielectric layer 151 and the first upper dielectric layers 152 and 153 may include the same material (e.g., silicon oxide), but are not limited thereto, and may include any suitable material known to one of ordinary skill in the art. The first lower dielectric layer 151 may include at least one of silicon oxide (SiO) and silicon nitride (SiN) applied to protect the through-electrodes 120 in a planarization process (e.g., CMP process). When the first upper dielectric layers 152 and 153 include a plurality of dielectric layers, the dielectric layer 153 located at the top may include a material that may be bonded to the second insulating layer 205 of the second chip structure 200, for example, silicon oxide (SiO) or silicon carbonitride (SiCN). However, as understood by one of ordinary skill in the art, the material forming the first dielectric layer 150 is not limited to the examples described above. Depending on the process, a boundary between the dielectric layer 153 located at the top among the first upper dielectric layers 152 and 153 and the second insulating layer 205 may not be clearly apparent.

The second chip structure 200 may be disposed on the first chip structure 100 and may include the second semiconductor chip 201, the second insulating layer 205, the second electrode pads 210, and the second dielectric layer 250. The second chip structure 200 may include components that are substantially the same as or similar to those of the first chip structure 100. Hereinafter, in the description of each component of the second chip structure 200, redundant descriptions with those of the first chip structure 100 are omitted.

The second semiconductor chip 201 may include a second circuit layer. The first circuit layer may include an integrated circuit including an interconnection structure electrically connecting individual devices to the second electrode pads 210. The height of the second semiconductor chip 201 in the Z-direction may be greater than the height of the first semiconductor chip. For example, the height of the first semiconductor chip may be less than the height of the second semiconductor chip. A width of the second semiconductor chip 201 in the X-direction or a width of the second semiconductor chip 201 in the Y direction may be substantially the same as that of the first semiconductor chip 101 or may be greater or smaller according to example embodiments.

The second insulating layer 205 may be disposed to surround the side surfaces of the second electrode pads 210. In one or more examples, the second insulating layer 205 may provide a bonding surface for bonding and combining with the first dielectric layer 150. The second insulating layer 205 may include a material that may be bonded to the first dielectric layer 150 or the first upper dielectric layer 152 and 153, for example, silicon oxide (SiO) or silicon carbonitride (SiCN).

The second electrode pads 210 may be in contact with the first upper electrode pads 130. The second electrode pads 210 may be connection terminals electrically connected to an integrated circuit of the second circuit layer. The second electrode pads 210 may be connection terminals (e.g., aluminum pads) of a bare chip, but are not limited thereto. According to example embodiments, the second electrode pads 210 may be a connection structure (e.g., a copper pad) formed on a connection terminal of a bare chip. The second electrode pads 210 may include any one of copper (Cu), nickel (Ni), titanium (Ti), aluminum (Al), gold (Au), silver (Ag), or alloys thereof. Between the second electrode pads 210 and the second insulating layer 205, a barrier layer including at least one of titanium (Ti), titanium nitride (TiN), tantalum (Ta), and tantalum nitride (TaN) may be formed.

In one or more examples, the second dielectric layer 250 may cover at least a portion of each of the second semiconductor chip 201 and the second insulating layer 205. The second dielectric layer 240 may provide a bonding surface for bonding and combining with the first dielectric layer 140. The second dielectric layer 240 may include at least one of silicon oxide (SiO), silicon nitride (SiN), and silicon carbonitride (SiCN). The second dielectric layer 241 may include a material that may be bonded to the first dielectric layer 150, for example, silicon oxide (SiO) or silicon carbonitride (SiCN). However, as understood by one of ordinary skill in the art, the material forming the second dielectric layer 240 is not limited to the examples described above, and may include any suitable material known to one of ordinary skill in the art.

In one or more examples, the bump structures 310 may be disposed on the first lower electrode pads 110, respectively. The bump structures 310 may connect the semiconductor package 1000 to an external device, such as a module substrate or main board. The bump structures 310 may include a pillar portion 311 in contact with each of the first lower electrode pads 110 and a solder portion 312 on the pillar portion 311. The pillar portion 311 may include copper (Cu) or an alloy of copper (Cu). In example embodiments, the solder portion 312 may include a low melting point metal, such as tin (Sn) or an alloy including tin (Sn). For example, solder portion 312 may include an Sn—Ag alloy or Sn—Ag—Cu alloy. In example embodiments, the bump structures 310 may include only the pillar portion 311 or only the solder portion 312.

The protective layer 350 may cover at least a portion of the bump structures 310. As illustrated in FIG. 2A, an outer surface of the protective layer 350 may have a step difference from the first outer surface 150AS and the second outer surface 150BS. The outer surface of the protective layer 350 may be inclined so that a width of the protective layer 350 narrows as the level of the protective layer 350 is lowered. The protective layer 350 may protect the first lower insulating pads 110 and the bump structures 310 from external physical/chemical damage. The protective layer 350 may include at least one of silicon oxide (SiO) and silicon nitride (SiN), but is not limited thereto. For example, the protective layer 350 may include a polymer, such as photo solder resist (PSR).

FIGS. 2A to 2F are enlarged views of region A of FIG. 1, according to example embodiments. FIG. 2A illustrates region A of the semiconductor package 1000 of FIG. 1, and FIGS. 2B to 2F illustrate additional views of region A, according to example embodiments.

Referring to FIGS. 2A and 2B together with FIG. 1, the first dielectric layer 150 may include a first portion 150A and a second portion 150B on the first portion 150A. The first outer surface 150AS of the first portion 150A may be located on an inner side of the first dielectric layer that is closer to the first semiconductor chip 101 than the second outer surface 150BS of the second portion of the first dielectric layer. Accordingly, the second outer surface 150BS of the second portion 150B may protrude farther in a direction away from the first semiconductor chip relative to the first outer surface 150AS of the first portion. The outer surfaces 150AS and 150BS of the first dielectric body layer 150 may have step differences. A distance D2 between the first outer surface 150AS and the second outer surface 150BS may be 0.5 μm to 10 μm. According to example embodiments, the distance D2 between the first outer surface 150AS and the second outer surface 150BS may be 2 μm to 5 μm or 1.5 μm to 2.5 μm. If the distance D2 between the first outer surface 150AS and the second outer surface 150BS is less than 0.5 μm, reliability may be reduced during the process. If the distance D2 between the first outer surface 150AS and the second outer surface 150BS is formed to greater than 10 μm, the structural stability of the semiconductor package may be reduced.

Referring to FIG. 1, the first portion 150A and the second portion 150B of the first dielectric layer 150 may be separated by a boundary in which the first dielectric layer 150 has a step. A height H1 of the first portion 150A may be substantially equal to a height H2 of the first insulating layer 105. For example, the portion in which the first dielectric layer 150 has a step different may be located on substantially the same level as that of an interface between the first semiconductor chip 101 and the first insulating layer 105. In example embodiments, the height H1 of the first portion 150A may be less than the height H2 of the first insulating layer. In the present example embodiment, the portion in which the first dielectric layer 150 has a step different may be located on a level lower than the interface between the first insulating layer 105 and the first semiconductor chip 101. According to example embodiments, the height H1 of the first portion 150A may be greater than the height H2 of the first insulating layer 105. In the present example embodiment, the portion in which the first dielectric layer 150 has a step difference may be located on a level lower than that of the interface between the first insulating layer 105 and the first semiconductor chip 101. In one or more examples, the height H1 of the first portion may be substantially equal to or smaller than the distance D2 between the first outer surface 150AS and the second outer surface 150BS.

An outer surface 350S of the protective layer 350 may be located on an inner side that is closer to the first semiconductor chip than the first outer surface 150AS. The outer surface 350S of the protective layer 350 may be inclined to be located on the inner side as the level of the protective layer is lowered. For example, the outer surface 350S of the protective layer 350 may be inclined so that the distance between the outer surface 350S of the protective layer 350 and the first outer surface 150AS increases from an upper end of the outer surface 350S of the protective layer 350 to a lower end thereof. A distance D1 between the upper end of the outer surface 350S of the protective layer 350 and the first outer surface 150AS may be substantially equal or less than a distance D2 between the first outer surface 150AS and the second outer surface 150BS. According to example embodiments, the distance D1 between the upper end of the outer surface 350S of the protective layer 350 may be greater than the distance D2 between the first outer surface 150AS and the second outer surface 150BS.

Referring to FIGS. 2C and 2D, in example embodiments, the first outer surface 150AS may be inclined so that the width of the first portion 150A narrows toward the protective layer 350. In example embodiments, as illustrated in FIG. 2D, the protective layer 350 may cover the first outer surface 150AS, and the outer surface 350S of the protective layer 350 may be located outside the first outer surface 150AS.

Referring to FIGS. 2E and 2F, the outer surface 350S of the protective layer 350 may be coplanar with the second outer surface 150BS. In example embodiments, the outer surface of the protective layer 350 may include a third upper outer surface 350S2 coplanar with the second outer surface 150BS and a third lower outer surface 350S1 inclined so that the width of the protective layer 350 narrows toward the lower surface of the protective layer 350.

The semiconductor package 1000 is not limited to the example embodiments illustrated in FIGS. 2A to 2F and may have various example embodiments of portion A. For example, the semiconductor package 1000 may have compatible features illustrated in FIGS. 2A to 2F at the same time. For example, the height H1 of the first portion 150A may be less than the height H2 of the first insulating layer 105 (FIG. 2B) and the first outer surface 150AS may have an inclination (FIG. 2C). In one or more examples, the semiconductor package 1000 may be interpreted as including additional features. For example, according to example embodiments, the second outer surface 150BS may have an uneven surface or the protective layer 350 may be omitted.

In the description of the following example embodiments, the same contents as those described above will be omitted.

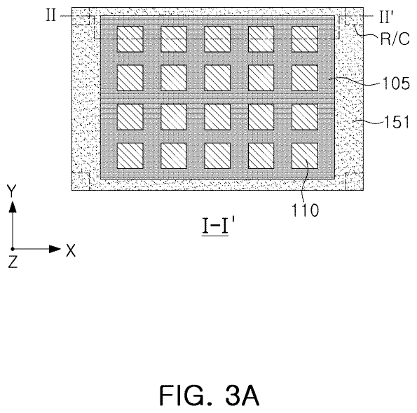

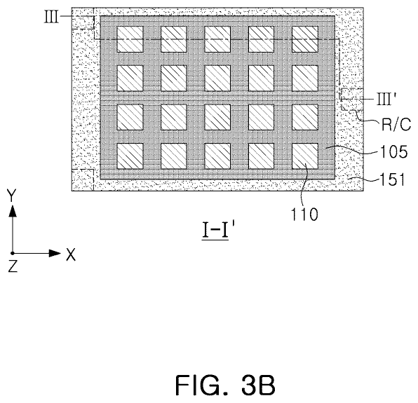

FIGS. 3A to 3B are plan views taken along line I-I′ of FIG. 1 according to example embodiments. FIG. 1 may be a cross-sectional view taken along line II-II′ of FIG. 3A or line III-III′ of FIG. 3B. Referring to FIGS. 3A and 3B together with FIG. 1, a recess region R/C, causing the first outer surface 150AS of the first portion 150A of the first dielectric layer 150 to have a step difference from the second portion 150BS, may exist. As understood by one of ordinary skill in the art, the size, number, and location of the recess region R/C may vary. According to example embodiments, the size, number, and location of the first lower electrode pads 110 illustrated in FIGS. 3A and 3B may vary.

The structure in which the first outer surface 150AS is located on an inner side that is closer to the first semiconductor chip 101 than the second outer surface 150BS as described above with reference to FIGS. 1 to 2F may exist on both sides of the first dielectric layer 150 at the same time as in the semiconductor package 1000 of FIG. 1, or may exist only on one side according to example embodiments.

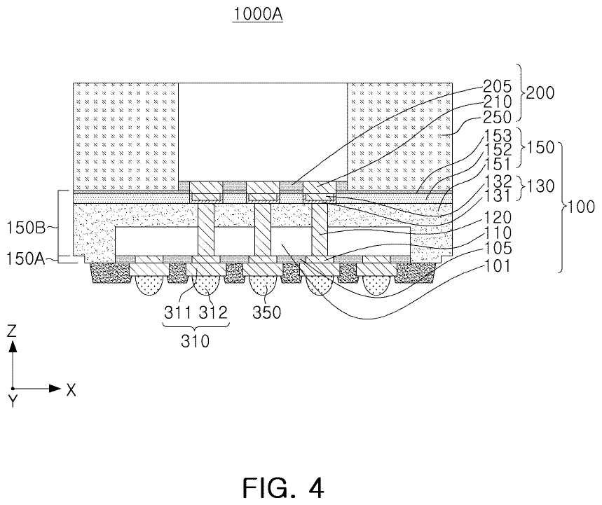

FIG. 4 is a cross-sectional view illustrating a semiconductor package according to example embodiments.

Referring to FIG. 4, in a semiconductor package 1000A, the second electrode pads 210 electrically connected to the second semiconductor chip 201 may be arranged to be fewer than the first lower electrode electrically connected to the first semiconductor chip 101. A width of the second semiconductor chip 201 in the X-direction may be less than that of the first semiconductor chip 101. According to example embodiments, the second semiconductor chip 201 may have a larger width in the X-direction than the first semiconductor chip 101. Other components not specifically described herein may have substantially the same characteristics as the components of the semiconductor package 1000 of FIG. 1.

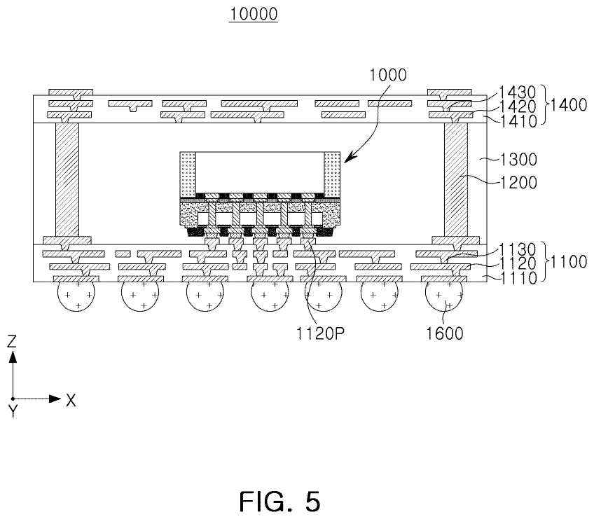

FIGS. 5 to 7 are cross-sectional views illustrating semiconductor packages according to example embodiments. FIGS. 5 to 7 illustrate example embodiments of semiconductor package structures on which the semiconductor packages of FIGS. 1 to 4 are mounted.

Referring to FIG. 5, a semiconductor package structure 10000 may include the semiconductor package 1000 described above with reference to FIG. 1, a lower redistribution structure 1100, a vertical power structure 1200, an encapsulant 1300, and an upper redistribution structure 1400.

In one or more examples, the lower redistribution structure 1100 may be a support substrate on which the semiconductor package 1000 is mounted, and may have an upper surface on which the semiconductor package 1000 is mounted and a lower surface opposing the upper surface. The lower redistribution structure 1100 may include a lower insulating layer 1110, lower redistribution layers 1120, and lower redistribution vias 1130.

The lower insulating layer 1110 may be disposed to surround at least a portion of the lower redistribution layers 1120. According to example embodiments, the lower insulating layer 1110 may include a plurality of layers stacked in the vertical direction (the Z-direction), and the boundary between the plurality of layers may not be apparent. The lower insulating layer 1110 may include an insulating resin. The insulating resin may include a thermosetting resin, such as an epoxy resin, a thermoplastic resin, such as polyimide, or a resin obtained by impregnating these resins with an inorganic filler, etc., such as prepreg, Ajinomoto build-up film (ABF), FR-4, bismaleimide triazine (BT), etc. For example, the lower insulating layer 1110 may include a photosensitive resin, such as photo-imageable dielectric (PID).

In one or more examples, the lower redistribution layers 1120 may include a plurality of lower redistribution layers located on different levels. One or more of the lower redistribution layers 1120 may be arranged to be adjacent to a lower surface of the lower insulating layer 1110, and others may be arranged to be adjacent to an upper surface of the lower insulating layer 1110. According to example embodiments, the lower redistribution layers 1120 may further include a pad portion 1120P disposed on the upper surface of the lower insulating layer 1110. The pad portion 1120P may be connected to the semiconductor package 1000 or the vertical power structure 1200. The lower redistribution layers 1120 may include metal materials, for example, copper (Cu), aluminum (Al), silver (Ag), tin (Sn), gold (Au), nickel (Ni), lead (Pb), and titanium (Ti).), or alloys thereof. The lower redistribution layers 1120 may perform various functions depending on the design. For example, the lower redistribution layers 1120 may include a ground (GND) pattern, a power (PWR) pattern, and a signal(S) pattern. Here, the signal(S) pattern may provide a transmission path for various signals, for example, data signals, etc., excluding the ground (GND) pattern, power (PWR) pattern, etc.

In one or more examples, the lower redistribution vias 1130 may penetrate through a partial region of the lower insulating layer 1110 to be electrically connected to the lower redistribution layers 1120. For example, the lower redistribution vias 1130 may interconnect lower redistribution layers 1120 on different levels. The lower redistribution vias 1130 may include a signal via, a ground via, and a power via. The lower redistribution vias 1130 may include, for example, copper (Cu), aluminum (Al), silver (Ag), tin (Sn), gold (Au), nickel (Ni), lead (Pb), titanium (Ti), or alloys thereof. The lower redistribution vias 1130 may be filled vias in which the inside of a via hole is filled with a metal material, or may be conformal vias in which a metal material extends along an inner wall of a via hole.

The semiconductor package 1000 may be disposed on the lower redistribution structure 1100. Referring to FIG. 1 together, the bump structures 310 of the semiconductor package 1000 may be disposed on the pad portion 1120P of the lower redistribution structure 1100 and may be electrically connected to the pad portion 1120P. According to example embodiments, an underfill layer may be disposed between the semiconductor package 1000 and the lower redistribution structure 1100. According to example embodiments, the underfill layer may have a molded underfill (MUF) structure integrated with the encapsulant 1300.

The vertical power structure 1200 may penetrate through the encapsulant 1300 to electrically connect the lower redistribution layers 1120 to the upper redistribution layers 1420. The vertical power structure 1200 may extend in the vertical direction (the Z-direction) within the encapsulant 1300. An upper surface of the vertical power structure 1200 may be exposed from the encapsulant 1300 and may be substantially coplanar with the upper surface of the encapsulant 1300. For example, the vertical power structure 1200 may have a post shape penetrating through the encapsulant 1300. However, as understood by one of ordinary skill in the art, the shape of the vertical power structure 1200 is not limited thereto. The vertical power structure 1200 may include a metal material, such as copper (Cu). According to example embodiments, a lower seed layer including titanium (Ti), copper (Cu), etc. may be disposed on the lower surface of the vertical power structure 1200.

In one or more examples, the encapsulant 1300 may seal at least a portion of the semiconductor package 1000 on an upper surface of the lower redistribution structure 1100. The encapsulant 1300 may include, for example, a thermosetting resin, such as an epoxy resin, a thermoplastic resin, such as polyimide, or prepreg obtained by impregnating these resins with an inorganic filler, ABF, FR-4, BT, or EMC. For example, the encapsulant 1300 may include EMC.

In one or more examples, the upper redistribution structure 1400 may be disposed on the semiconductor package 1000 and the encapsulant 1300 and may include an upper insulating layer 1410, upper redistribution layers 1420, and upper redistribution vias 1430.

In one or more examples, the upper insulating layer 1410 may include an insulating resin. The insulating resin may include a thermosetting resin, such as an epoxy resin, a thermoplastic resin, such as polyimide, or a resin obtained by impregnating these resins with an inorganic filler, etc., such as prepreg, ABF, FR-4, BT, or PID. The upper insulating layer 1410 may include a plurality of layers stacked in the vertical direction (the Z-axis direction). According to the process, the boundaries between the plurality of layers may not be apparent.

The upper redistribution layers 1420 may be disposed on or within upper insulating layer 1410 and may redistribute the vertical power structure 1200. The upper redistribution layer 1420 may include a metal material including, for example, copper (Cu), aluminum (Al), silver (Ag), tin (Sn), gold (Au), nickel (Ni), lead (Pb), titanium (Ti), or alloys thereof. The upper redistribution layers 1420 may include more or fewer redistribution layers than those illustrated in the drawing.

In one or more examples, the upper redistribution vias 1430 may penetrate through the upper insulating layer 1410 to be electrically connected to the upper redistribution layer 1420. For example, the upper redistribution vias 1430 may interconnect upper redistribution layers 1420 on different levels. For example, the upper redistribution vias 1430 may interconnect the upper redistribution layer 1420 to the vertical power structure 1200. The upper redistribution vias 1430 may be filled vias in which the inside of a via hole is filled with a metal material, or may be conformal vias in which a metal material extends along an inner wall of the via hole. The upper redistribution vias 1430 may include, for example, copper (Cu), aluminum (Al), silver (Ag), tin (Sn), gold (Au), nickel (Ni), lead (Pb), titanium (Ti), or alloys thereof. The upper redistribution vias 1430 may be filled vias in which the inside of the via hole is filled with a metal material, or may be conformal vias in which a metal material extends along the inner wall of the via hole.

In one or more examples, the external connection conductors 1600 may be disposed on the lower surface of the lower redistribution structure 1100. The external connection conductors 1600 may be electrically connected to the semiconductor package 1000 and the vertical power structure 1200 through the lower redistribution layers 1120. The semiconductor package structure 10000 may be connected to an external device, such as a module substrate or system board, through external connection conductors 1600. For example, the external connection conductors 1600 may be a low melting point metal, such as tin (Sn) or a tin-silver-copper (Sn—Ag—Cu) alloy including tin (Sn) or a tin-aluminum-copper (Sn—Al—Cu) alloy, etc. According to example embodiments, the external connection conductors 1600 may have a shape that is a combination of a pillar (or underbump metal) and a ball. The pillar may include copper (Cu) or an alloy of copper (Cu), and the ball may include a solder ball. According to example embodiments, the lower redistribution structure 1100 may include a resist layer protecting the external connection conductors 1600 from external physical and chemical damage.

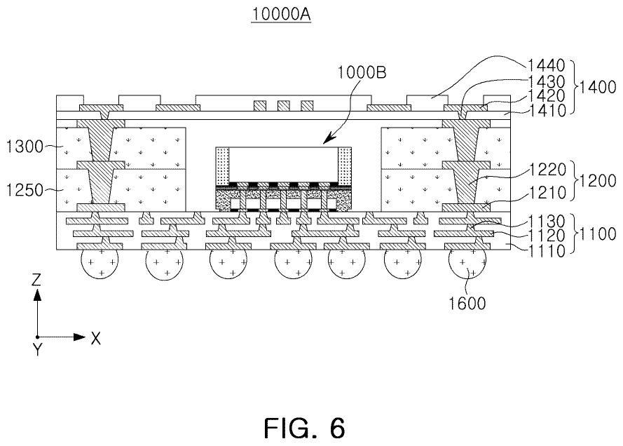

Referring to FIG. 6, the semiconductor package structure 10000A may include a semiconductor package 1000B. The semiconductor package 1000B may have a structure in which the bump structures 310 and the protective layer 350 are omitted from the semiconductor package 1000 of FIG. 1.

The semiconductor package structure 10000A may further include an intermediate insulating layer 1250 covering at least a portion of the vertical power structure 1200. The intermediate insulating layer 1250 may be composed of a plurality of insulating layers. The vertical power structure 1200 may include an intermediate interconnection layer 1210 and an intermediate via 1220. The intermediate interconnection layer 1210 may be disposed on an upper surface of the lower redistribution structure 1100, an upper surface of the intermediate insulating layer 1250, etc., and the intermediate via 1220 may penetrate through the intermediate insulating layer 1250 to connect the intermediate interconnection layers 1210.

In one or more examples, the upper redistribution structure 1400 may include a passivation layer 1440 covering at least a portion of the upper redistribution layer 1420 on the upper insulating layer 1410. The passivation layer 1440 may protect the upper redistribution structure 1400 from external physical and chemical damage. For example, the passivation layer 180 may include an insulating material, such as prepreg, ABF, FR-4, BT, solder resist, or photo solder resist (PSR).

Other components not specifically described herein may have substantially the same characteristics as those of the semiconductor package structure 10000 of FIG. 5.

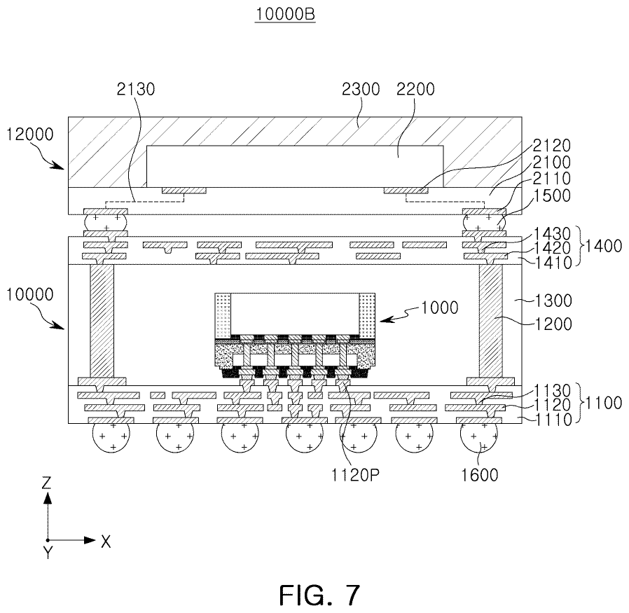

Referring to FIG. 7, a semiconductor package structure 10000B may include a first package 10000 and a second package 12000 on the first package 10000. The first package 10000 is illustrated to be the same as the semiconductor package structure illustrated in FIG. 5, but may be replaced with a semiconductor package structure having the same characteristics as those of the semiconductor package structure 10000A illustrated in FIG. 6 according to example embodiments.

In one or more examples, the second package 12000 may include a redistribution substrate 2100, a second package semiconductor chip 2200, and a second encapsulant 2300. The redistribution substrate 2100 may include a lower pad 2110 that isphysically and electrically connected to a connection metal body 1500 on a lower surface thereof. The redistribution substrate 2100 may include an upper pad physically and electrically connected to the second semiconductor chip 2200 on an upper surface thereof. The redistribution substrate 2100 may include a redistribution circuit 2130 electrically connecting the lower pad 2110 to the upper pad 2120.

In one or more examples, the second encapsulant 2300 may include a material the same as or similar to that of the encapsulant 1300 of the first package 10000.

In one or more examples, the connection metal body 1500 may be electrically connected to the redistribution circuit 2130 inside the second redistribution substrate 2100 through the lower pad 2110 of the redistribution substrate 2100.

In such a package-on-package (POP) structure, the semiconductor package 1000 of FIG. 1 may be applied not only to the first package 10000, but also to the second package 12000.

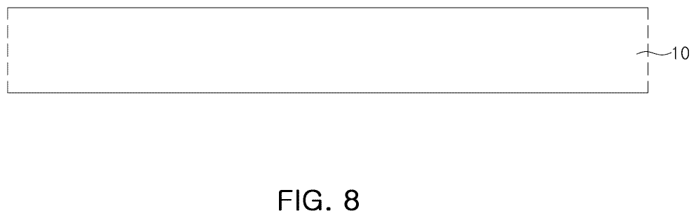

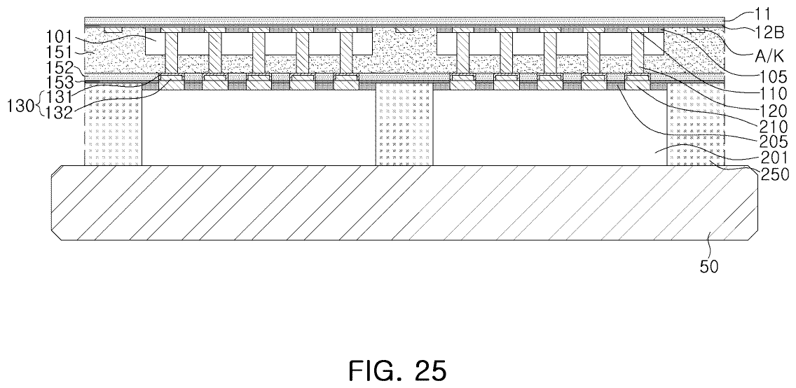

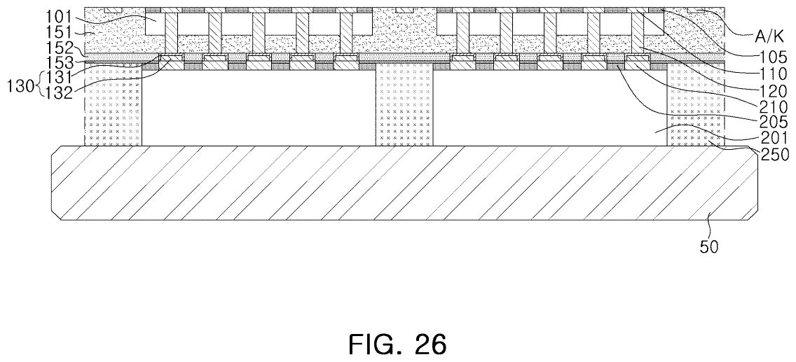

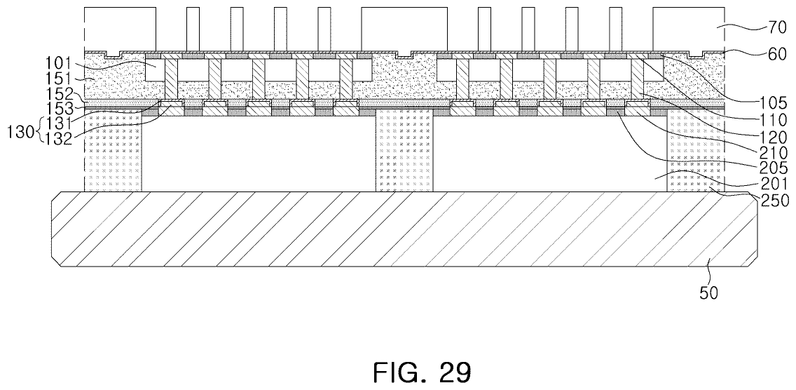

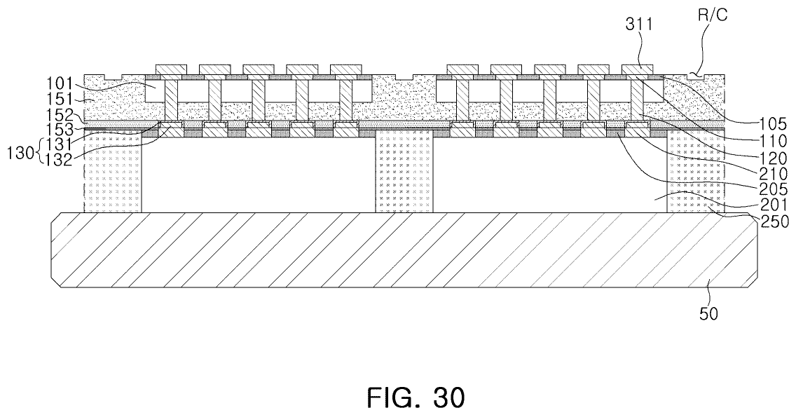

FIGS. 8 to 35 are views illustrating a manufacturing process of a semiconductor package according to example embodiments. FIGS. 8 to 35 illustrate a process illustrating a manufacturing process of the semiconductor package 1000 of FIG. 1.

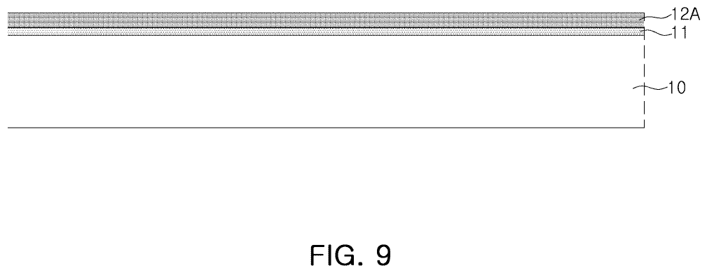

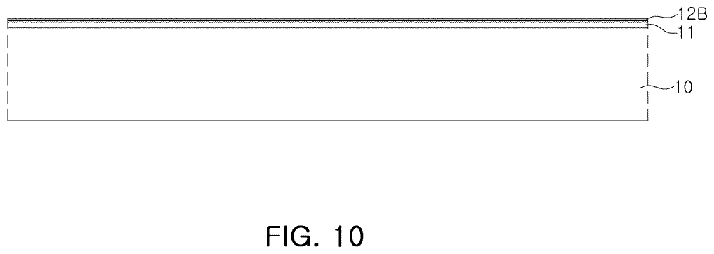

Referring to FIGS. 8 to 10, temporary bonding layers 11 and 12A may be formed on a recombination carrier 10. In order to illustrate the manufacturing process of the semiconductor package 1000 illustrated in FIG. 1, only one unit of the recombination carrier 10 is illustrated. However, as understood by one of ordinary skill in the art, the manufacturing process may be extended to any desired number of recombination carriers. For example, the recombination carrier 10 may be a 6-inch, 8-inch, 12-inch, etc. silicon wafer including dozens or more of the units illustrated in the drawing. Hereinafter, for convenience of description, the manufacturing process of the semiconductor package will be described focusing on one unit illustrated in the drawing. As illustrated in FIG. 9, the temporary bonding layers 11 and 12A may include a plurality of bonding layers. The lower bonding layer 11 may be an oxide layer including silicon oxide (SiO), and the upper bonding layer 12A may be a layer including silicon carbonitride (SiCN). The temporary bonding layers 11 and 12A may be formed using a PVD or CVD process. The upper bonding layer 12A may form an upper bonding layer 12B flattened by a chemical mechanical polishing (CMP) process. FIG. 10 illustrates a flattened upper bonding layer 12B.

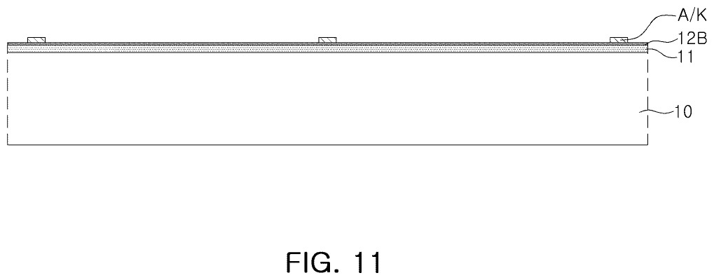

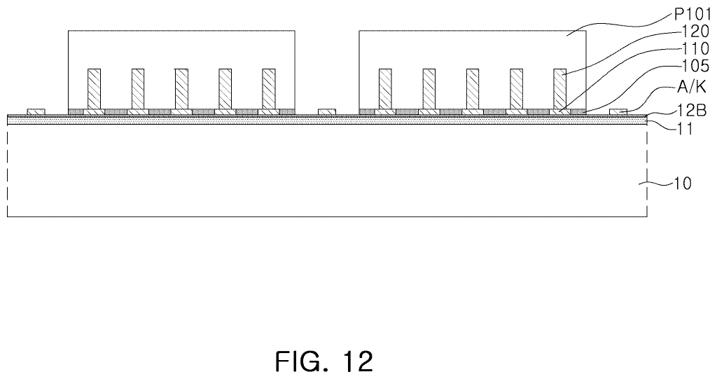

Referring to FIGS. 11 and 12, an alignment key A/K may be formed on the flattened upper bonding layer 12B. The alignment key A/K may be formed using, for example, an electroplating process. The alignment key A/K may include a plating seed layer including titanium (Ti), etc. and a plating layer including copper (Cu), etc. Thereafter, a preliminary first semiconductor chip P101 may be disposed on the upper bonding layer 12B. In one or more examples, the preliminary first semiconductor chip P101 may be disposed in a position determined through the alignment key A/K. The preliminary first semiconductor chip P101 may include a first insulating layer 105, first lower electrode pads 110, and through-electrodes 120. The preliminary first semiconductor chip P101 may be a known good die (KGD) for which testing has been completed. The preliminary first semiconductor chip P101 may be an IC chip having thickness not adjusted yet through a back-grinding process.

In one or more examples, the first insulating layer 105 and the first lower electrode pads 110 may be attached to the flattened upper bonding layer 12B by a thermal compression process. The thermal compression process may be performed under a thermal atmosphere ranging from about 100° C. to about 300° C. However, the temperature of the thermal atmosphere is not limited to the aforementioned range and may vary. A boundary between the first insulating layer 121 and the flattened upper bonding layer 12B may not be apparent.

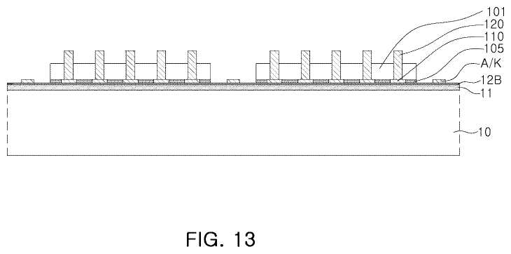

Referring to FIG. 13, according to example embodiments, by applying a back grinding process and an etch-back process to the preliminary first semiconductor chip P101, a thickness of the preliminary first semiconductor chip P101 may be reduced, thereby forming the first semiconductor chip 101, and the through-electrodes 120 may protrude from the upper surface of the first semiconductor chip 101.

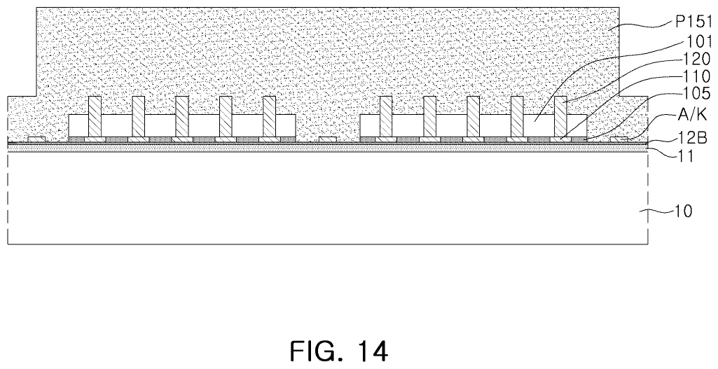

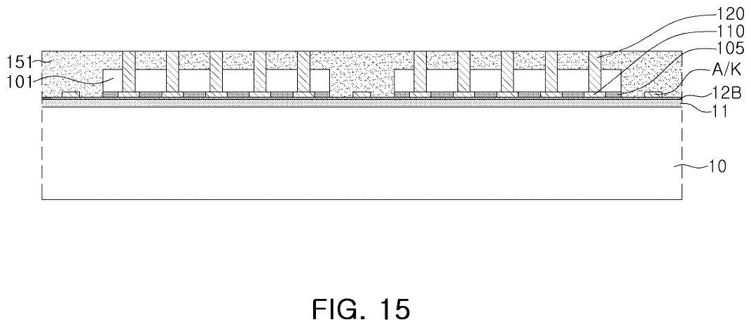

Referring to FIGS. 14 and 15, according to example embodiments, a preliminary first lower dielectric layer P151 may be formed. The preliminary first lower dielectric layer P151 may be formed to cover the alignment key A/K, the first insulating layer 105, the first semiconductor chip 101, and the through-electrodes 120. The preliminary first lower dielectric layer P151 may include silicon oxide (SiO) and may be formed using a PVD or CVD process.

Thereafter, the first lower dielectric layer 151 may be formed by applying a CMP process to the preliminary first lower dielectric layer P151. The first lower dielectric layer 151 may surround a side surface of each of the through-electrodes 120, and upper surfaces of the through-electrodes 120 may be exposed.

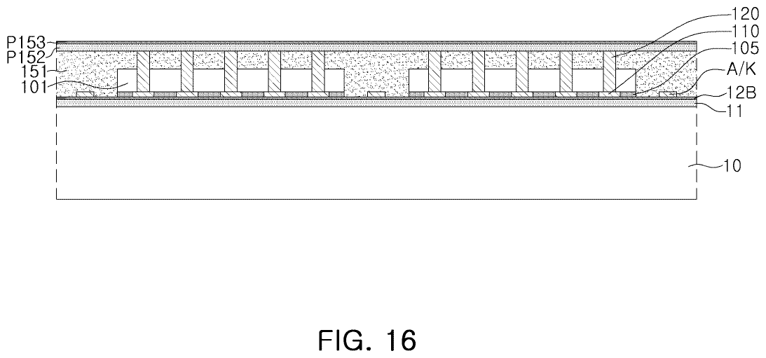

Referring to FIG. 16, according to example embodiments, preliminary first upper dielectric layers 152 and 153 may be formed on the first lower dielectric layer 151. The preliminary first upper dielectric layers P152 and P153 may include a plurality of dielectric layers. The preliminary first upper dielectric layers P152 and P153 may include silicon oxide (SiO) and may be formed using a PVD or CVD process.

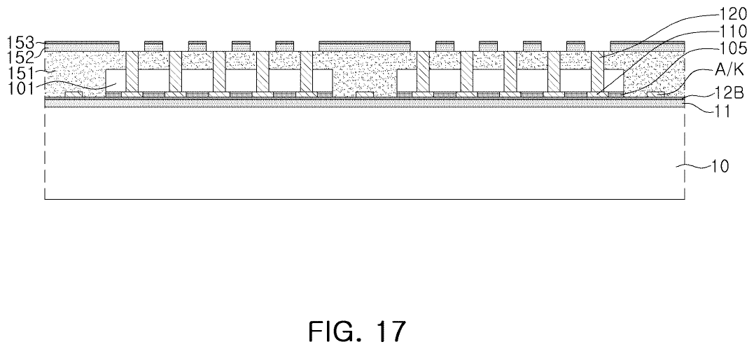

Referring to FIG. 17, according to example embodiments, the first upper dielectric layers 152 and 153 may be formed by patterning the preliminary first upper dielectric layers P152 and P153 using a photosensitive material layer and a photolithography process to expose the upper surfaces of the through-electrodes 120.

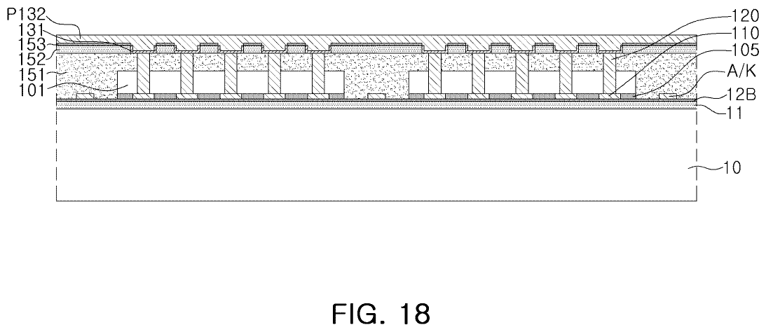

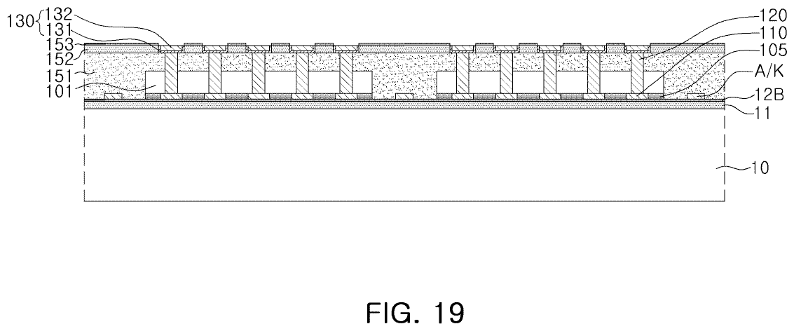

Referring to FIGS. 18 to 19, according to example embodiments, a seed layer 131 covering the exposed upper surfaces of the through-electrodes 120, the exposed upper surface of the first lower dielectric layer 151, and the exposed side surfaces of the first upper dielectric layers 152 and 153 may be formed. Thereafter, a preliminary conductive layer P132 covering the first upper dielectric layers 152 and 153 and the seed layer 131 may be formed, and the preliminary conductive layer P132 on the first upper dielectric layers 152 and 153 may be removed to form a conductive layer 132 on the seed layer 131. Referring to FIG. 1 together, each seed layer 131 and the conductive layer 132 may form the first upper electrode pads 130.

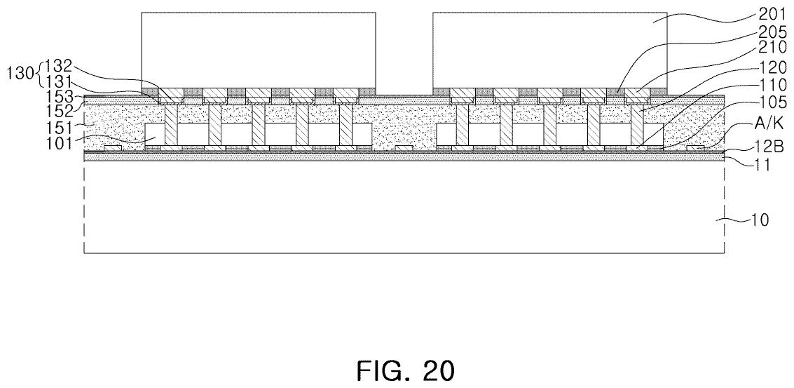

Referring to FIG. 20, according to example embodiments, there may be formed the second electrode pads 210, the second insulating layer 205 surrounding the side surfaces of the second electrode pads 210, and the second semiconductor chip 201 on the second electrode pads 210 and the second insulating layer 205. Although not specifically illustrated, in order to align and form the second electrode pads 210 on the conductive layer 132, an alignment key or an align layer may be formed on the first upper dielectric layers 152 and 153.

The second electrode pads 210 may be formed to contact the conductive layer 132, and the second insulating layer 205 may surround the side surfaces of the second electrode pads 210 and may contact the first upper dielectric layers 152 and 153. The second semiconductor chip 201 may be a known good die (KGD) for which testing has been completed.

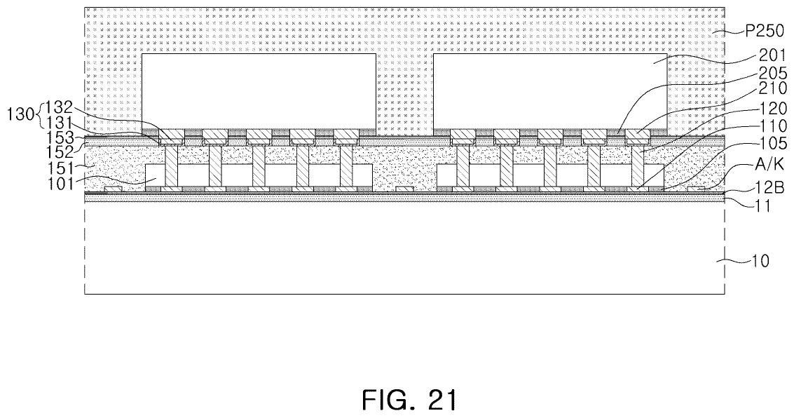

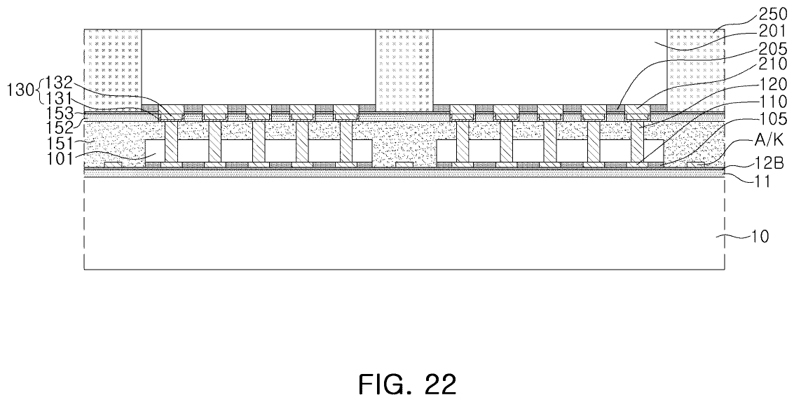

Referring to FIGS. 21 and 22, according to example embodiments, a preliminary second dielectric layer P250 covering the first upper dielectric layers 152 and 153, the second insulating layer 205, and the second semiconductor chip 201 may be formed. The preliminary second dielectric layer 250 may include silicon oxide (SiO) and may be formed using a PVD or CVD process. By applying a CMP process to the preliminary second dielectric layer 250, the second dielectric layer 250 having a flat upper surface may be formed, and the upper surface of the second semiconductor chip 201 may be exposed.

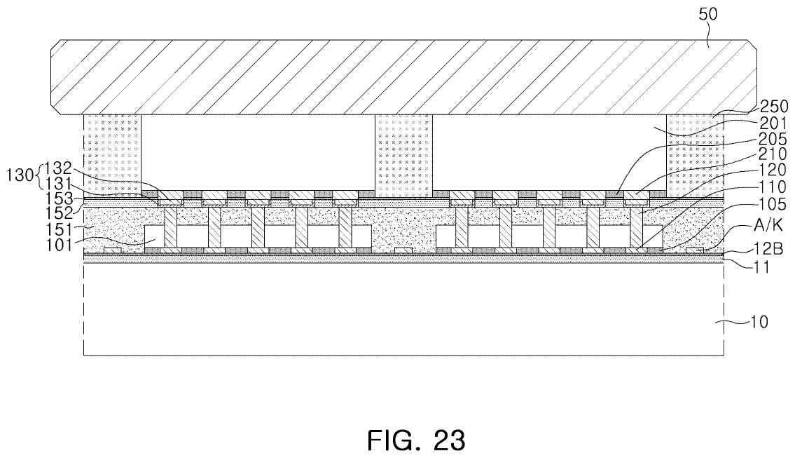

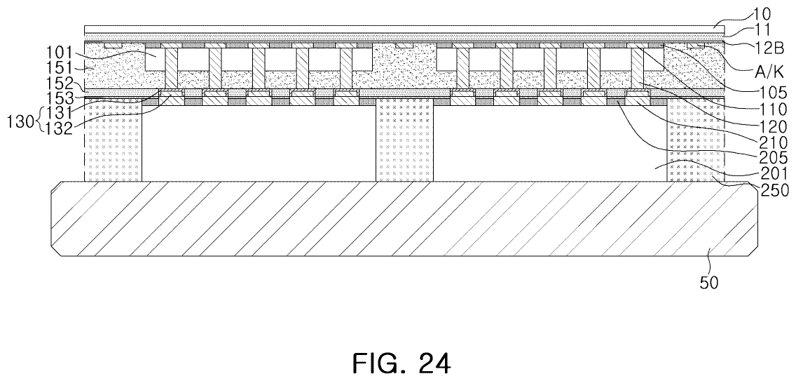

Referring to FIG. 23, according to example embodiments, a carrier 50 may be attached to the upper surface of the second dielectric layer 250 and the upper surface of the second semiconductor chip 201. The carrier 50 may be a device for turning the structure formed in FIGS. 8 to 22 upside down in order to proceed with a process on the lower surface of the first semiconductor chip 101 described in the process illustrated in FIG. 24 and the following drawings.

Referring to FIGS. 24 to 26, according to example embodiments, the recombination carrier 10 may be exposed upwardly by the carrier 50, and the recombination carrier 10 and the temporary bonding layers 11 and 12B may be sequentially removed to expose the alignment key A/K, the first insulating layer 105, and the first lower electrode pads 110. The recombination carrier 10 and the temporary bonding layers 11 and 12B may be removed by combining a grinding process and an etching process. According to example embodiments, a portion of the temporary bonding layers 11 and 12B may remain to form a portion of the protective layer 350 (see FIG. 1) covering the first lower electrode pads 110.

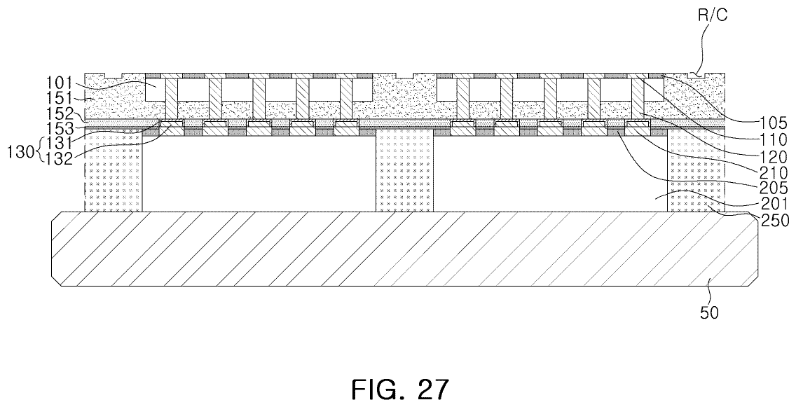

Referring to FIG. 27, according to example embodiments, the alignment key A/K may be removed to form the recess region R/C. The recess region R/C may be used as an alignment key when forming components to be formed in a subsequent process. Accordingly, the subsequent process may be performed even without forming a separate alignment key or alignment layer, thereby simplifying the process and reducing process costs.

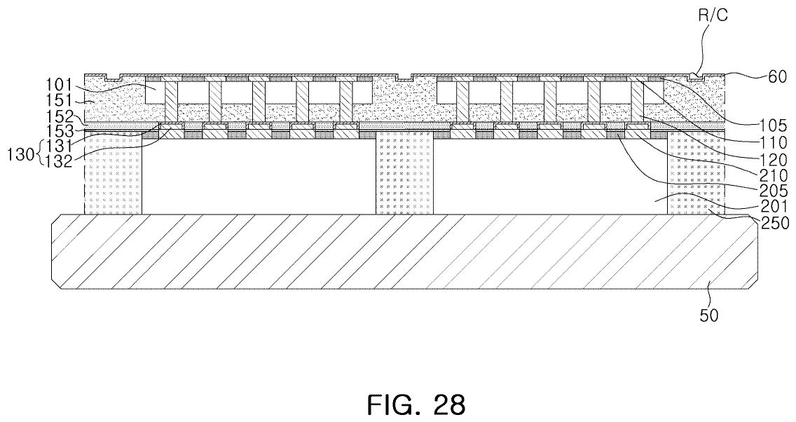

Referring to FIGS. 28 to 30, according to example embodiments, a temporary bond layer 60 covering the recess region R/C and the exposed first insulating layer 105, first lower electrode pads 110, and first lower dielectric layer 151 may be formed. A temporary lower pattern 70 may be formed on the temporary bonding layer 60 to form a pillar portion 311 on the first lower electrode pads 110. The temporary lower pattern 70 may include openings exposing at least a portion of the first lower electrode pads 110. The openings may be formed in positions determined by using the recess region R/C as an alignment key. Thereafter, the exposed temporary bonding layer 60 portion in the openings may be removed and the pillar portion 311 may be formed. After the pillar portion 311 is formed, the temporary bonding layer 60 and the temporary lower pattern 70 may be removed.

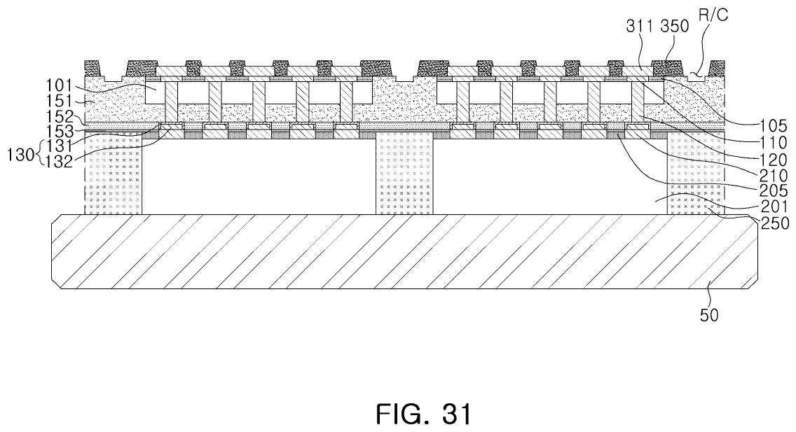

Referring to FIG. 31, according to example embodiments, the protective layer 350 may be formed to cover at least a portion of the pillar portion 311 on the first lower dielectric layer 151. The protective layer 350 may be formed not to cover the recess region R/C, but according to example embodiments, the protective layer 350 may be formed to cover at least a portion of the recess region R/C. When the protective layer 350 is formed to cover at least a portion of the recess region R/C, the semiconductor package including the features of FIGS. 2D to 2F may be formed.

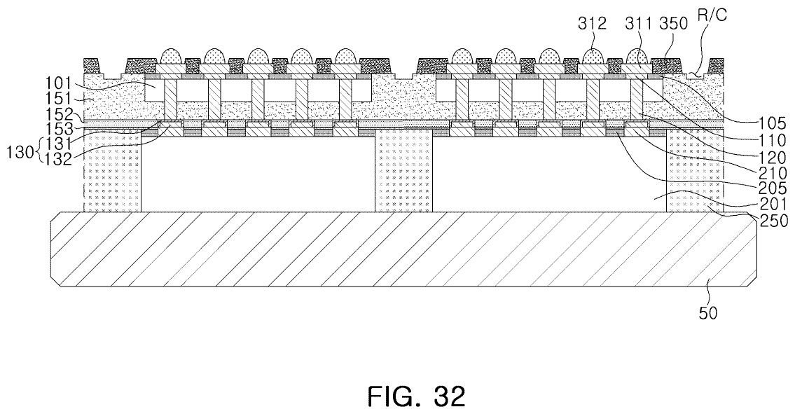

Referring to FIG. 32, according to example embodiments, the solder portion 312 may be formed on the pillar portion 311. The pillar portion 311 and the solder portion 312 may form the bump structures 310 (see FIG. 1).

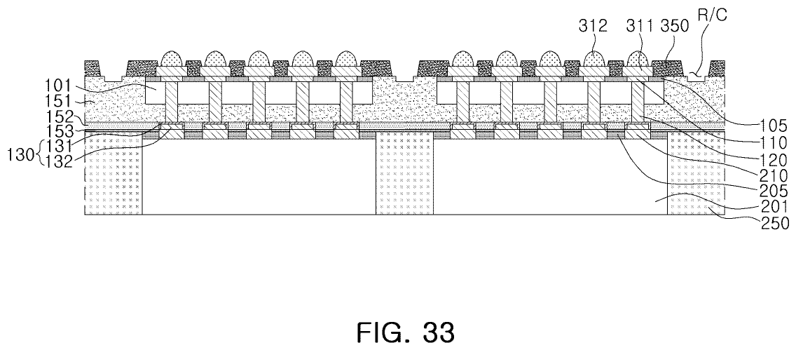

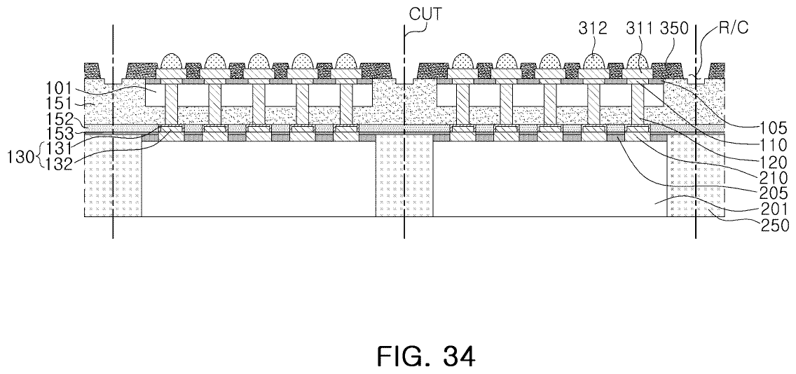

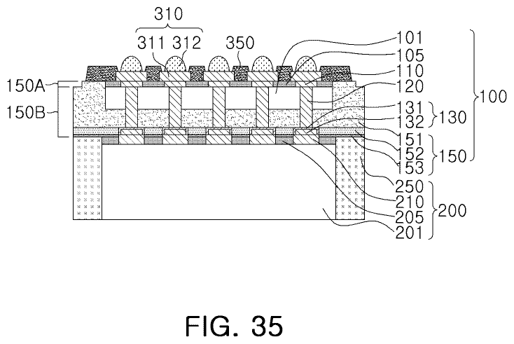

Referring to FIGS. 33 to 35, according to example embodiments, the carrier 50 may be removed, and cutting (FIG. 34) may be performed on a semiconductor chip basis to form a semiconductor package, as illustrated in FIG. 35.

According to embodiments of the present embodiments, the semiconductor package having simplified processes and improved reliability may be provided by using the pattern formed by the alignment key in subsequent processes.

While example embodiments have been illustrated and described above, it will be apparent to those skilled in the art that modifications and variations could be made without departing from the scope of the present embodiments as defined by the appended claims.

What is claimed is:

1. A semiconductor package comprising:
a first semiconductor chip having first and second surfaces opposing each other;
first lower electrode pads on the first surface of the first semiconductor chip and electrically connected to the first semiconductor chip;
a first insulating layer surrounding a side surface of each of the first lower electrode pads on the first surface of the first semiconductor chip;
through-electrodes penetrating through at least a portion of the first semiconductor chip and protruding from the second surface of the first semiconductor chip;
first upper electrode pads on the through-electrodes and electrically connected to the first semiconductor chip through the through-electrodes;
a first dielectric layer covering at least a portion of each of the first insulating layer, the first semiconductor chip, the through-electrodes, and the first upper electrode pads on the through-electrodes;
a second semiconductor chip on the first dielectric layer;
second electrode pads on a first surface of the second semiconductor chip and electrically connected to the second semiconductor chip and the first upper electrode pads on the through-electrodes;
a second insulating layer surrounding side surfaces of the second electrode pads on the first surface of the second semiconductor chip;
a second dielectric layer covering at least a portion of each of the second semiconductor chip and the second insulating layer;
bump structures patched below the first lower electrode pads on the first surface of the first semiconductor chip; and
a protective layer covering at least a portion of the bump structures,
wherein the first dielectric layer comprises a first portion and a second portion on the first portion of the first dielectric layer, and
a first outer surface of the first portion of the first dielectric layer is located on an inner side that is closer to the first semiconductor chip than a second outer surface of the second portion of the first dielectric layer.

2. The semiconductor package of claim 1, wherein an outer surface of the protective layer is inclined so that a width of the protective layer narrows in a direction away from the first semiconductor chip.

3. The semiconductor package of claim 1, wherein an outer surface of the protective layer is located closer to the first semiconductor chip than the first outer surface of the first portion.

4. The semiconductor package of claim 1, wherein the first portion surrounds at least a portion of a side surface of the first insulating layer, and the second portion surrounds at least a portion of a side surface of the first semiconductor chip.

5. The semiconductor package of claim 1, wherein the protective layer covers the first outer surface of the first portion, and an outer surface of the protective layer is located on an inner side of the second outer surface of the second portion.

6. The semiconductor package of claim 1, wherein the first outer surface of the first portion is inclined in a direction away from the first semiconductor chip.

7. The semiconductor package of claim 1, wherein the first dielectric layer includes a first lower dielectric layer and a first upper dielectric layer, the first lower dielectric layer surrounding a side surface of the first insulating layer and a side surface of each of the through-electrodes, and the first upper dielectric layer surrounding a side surface of each of the upper electrode pads and contacting the second insulating layer on the first lower dielectric layer.

8. The semiconductor package of claim 7, wherein the first lower dielectric layer comprises the entirety of the first portion of the first dielectric layer and at least a portion of the second portion of the first dielectric layer.

9. The semiconductor package of claim 7, wherein the first upper dielectric layer and the second insulating layer comprise at least one of silicon oxide, silicon nitride, and silicon carbonitride.

10. The semiconductor package of claim 1, wherein the bump structures each include a pillar portion in contact with the first lower electrode pads on the first surface of the first semiconductor chip and a solder portion disposed on a first surface of the pillar portion.

11. The semiconductor package of claim 1, wherein the first upper electrode pads on the through-electrodes and the second electrode pads on the first surface of the second semiconductor chip are in contact with each other.

12. The semiconductor package of claim 11, wherein the first upper electrode pads on the through pads and the second electrode pads on the first surface of the second semiconductor chip comprise copper (Cu).

13. The semiconductor package of claim 1, wherein a distance between the first outer surface of the first portion of the first dielectric layer and the second outer surface of the second portion of the first dielectric layer is 0.5 μm to 10 μm.

14. A semiconductor package comprising:
first and second chip structures stacked in a first direction,
wherein the first chip structure incudes:
a first semiconductor chip,
first lower electrode pads electrically connected to the first semiconductor chip,
a first insulating layer surrounding each of the first lower electrode pads,
through-electrodes penetrating through at least a portion of the first semiconductor chip,
first upper electrode pads on the through-electrodes, and
a first dielectric layer covering a portion of each of the first insulating layer, the first semiconductor chip, the through-electrodes, and the first upper electrode pads on the through-electrodes,
wherein the second chip structure comprises:
a second semiconductor chip,
second electrode pads electrically connected to the second semiconductor chip and the first upper electrode pads on the through-electrodes,
a second insulating layer surrounding the second electrode pads and contacting the first dielectric layer, and
a second dielectric layer covering at least a portion of each of the second semiconductor chip and the second insulating layer,
wherein the first dielectric layer comprises a first portion surrounding at least a portion of a side surface of the first insulating layer and a second portion surrounding a side surface of the first semiconductor chip, and
wherein a first outer surface of the first portion and a second outer surface of the second portion have a step difference.

15. The semiconductor package of claim 14, wherein the second outer surface of the second portion protrudes relative to the first outer surface of the first portion.

16. The semiconductor package of claim 14, wherein a height of the first semiconductor chip is smaller than a height of the second semiconductor chip.

17. The semiconductor package of claim 14, further comprising:
bump structures disposed below the first chip structure; and
a protective layer covering at least a portion of the bump structures.

18. The semiconductor package of claim 17, wherein an outer surface of the protective layer has a step difference from the first outer surface and the second outer surface.

19. The semiconductor package of claim 14, wherein the first upper electrode pads on the through-electrodes each include a conductive layer and a seed layer covering side and lower surfaces of the conductive layer,
wherein the conductive layer comprises copper (Cu), and
wherein the seed layer comprises titanium (Ti).

20. A semiconductor package comprising:
a first semiconductor chip;
first lower electrode pads below the first semiconductor chip and electrically connected to the first semiconductor chip;
a first insulating layer surrounding a side surface of each of the first lower electrode pads;
through-electrodes penetrating through at least a portion of the first semiconductor chip and protruding from an upper surface of the first semiconductor chip;
first upper electrode pads on the through-electrodes and electrically connected to the first semiconductor chip through the through-electrodes;
a first dielectric layer covering a portion of each of the first insulating layer, the first semiconductor chip, the through-electrodes, and the first upper electrode pads;
a second semiconductor chip on the first dielectric layer;
second electrode pads on a first surface of the second semiconductor chip and electrically connected to the second semiconductor chip and the first upper electrode pads on the through-electrodes; and
a second insulating layer surrounding side surfaces of the second electrode pads on the first surface of the second semiconductor chip,
wherein the first dielectric layer comprises a first portion having a first width and a second portion having a second width greater than the first width on the first portion.
